(19) United States
(12) Patent Application Publication
(10) Pub. No.: US 2009/0045828 A1
(43) Pub. Date: Feb. 19, 2009

(54) Fine Pitch Testing Substrate Structure And Method Of Manufacturing The Same

(76) Inventors: Li-Kuo Chen, Pingzhen City (TW); Wen-Tsung Lee, Jhongli City (TW)

Correspondence Address: WPAT, PC;INTELLECTUAL PROPERTY ATTORNEYS, 2030 MAIN STREET, SUITE 1300, IRVINE, CA, 92614, US

(21) Appl. No.: 12/186,914

(22) Filed: Aug. 6, 2008

(30) Foreign Application Priority Data
Aug. 7, 2007 (TW) 096129112

(51) Int. Cl. G01R 1/073; G01R 3/00

(52) U.S. Cl. 324/754; 29/874

(57) ABSTRACT

The present invention provides a newly designed testing substrate for solving the problem with respect to fine pitches, and a method of manufacturing the testing substrate. The wiring space within the fine pitch can be enlarged by means of a circuit design with through holes, blind vias and stack vias, in association with process technologies for fine lines, blind vias, buried vias and filling vias. The manufactured testing substrate comprises a resting substrate and a probe base, being applicable to the test for IC's or packaged articles.

### BACKGROUND OF THE INVENTION

1. Field of the Invention

The present invention relates to a fine pitch testing substrate structure and a method of manufacturing the same. According to the present invention, the wiring space within the fine pitches can be enlarged, by means of a circuit design with through holes, blind vias and stack vias in association with process technologies for fine lines, blind vias, buried vias and filling vias.

2. Descriptions of the Related Art

The manufacturing flow in semiconductor industry is constituted of five major stages, i.e. IC (integrated circuit) design, wafer fabrication, wafer test, IC package and final test. In the stage of wafer test, electric check is performed for each die on a tested wafer so as to tell good and bad dies apart. To test a wafer, the probe on a probe card is used to pin the pad that is on a die so as to make an electric contact and, then, test signals obtained by the probe are sent to an automatic testing equipment (ATE) for analysis and determination; thus, results of electric test for each die on the wafer can be gathered. As the progress of semiconductor process technologies, the sizes of semiconductor devices become smaller and smaller and IC's become more and more precise. The sizes of semiconductor devices have reached the deep sub-micro scale from the sub-micro scale. Test and validation technologies need be continuously promoted to meet the development in semiconductor process technologies. Among others, test technologies relevant directly to IC is the most important, in which IC testing cards play a critical role.

Since the sizes of semiconductor devices become smaller and smaller, the legs thereof must be closer and closer, leading to more and more significant parasitic effect that derives more and more severe problems of electric interference and attenuation on IC testing cards. Thus, the processes become more and more complicated and require more and more precision.

FIG. 1 is a schematic sectional view of a conventional IC testing card, which is disclosed by TW PATENT No. 00578910. As shown in FIG. 1, an IC testing card 100 comprises a circuit board 110 and a probe base 200; the circuit board 110 and the probe base 200 are components of the two-piece IC testing card 100. The probe base 200 has a plurality of probes 210 disposed at a first pitch 220, wherein the first pitch 220 is approximately equal to the pitch between signal contacts 240 disposed on a tested IC device 230. The probes 210 can be used to electrically contact the tested IC device 230 and to gather electric characteristics of the tested IC device 230.

The circuit board 110 has an upper surface 122 and a lower surface 123. On the upper surface 122, there is a plurality of testing contacts 124 disposed so that the testing contacts 124 can be connected directly to a testing machine. The testing contacts 124 are spaced from each other at a second pitch 126, wherein the second pitch 126 can be designed according to specifications of the testing equipment connected to the plurality of testing contacts 124. The second pitch 126, which spaces the testing contacts 124 from each other, is larger than the first pitch 220, which spaces the probes 210.

FIG. 2 illustrates a method of manufacturing the circuit board 110 shown in FIG. 1. As shown in FIG. 2, the circuit board 110 is laminated with four laminates 120, 130, 140, 150. The laminates 120, 130, 140, 150 can be made from polymide or FR-4 (flame retardant 4) in which conducting metals 138 are preformed. The pitch spacing the conducting metals 138 of the laminates 120 is corresponding to the second pitch 126 spacing the testing contacts 124. The pitch spacing the conducting metals 138 of the laminates 150 is corresponding to the first pitch 220 spacing the testing contacts 210. After the preparation of the laminates 120, 130, 140, 150 is finished, a process of thermal lamination is performed at 120° C. so that the laminates 120, 130, 140, 150 are laminated together to form the circuit board 110. The conducting metals 138 of those laminates form the conducting channels of the circuit board 110.

Conventional designs for IC testing cards and processes for circuit boards have the following disadvantages.

1. Print circuit boards are made from glass fiber material such as polymide or FR-4 and, therefore, prepreg to be used as adhering medium is stacked between the laminates of the circuit board before lamination. In the process of thermal lamination at 120° C. to laminate a plurality of laminates and form the board, the conducting metals of the laminates can be isolated from those of other laminates and cannot be interconnected. Moreover, in terms of the product specification of copper substrate, laid by Nan Ya Plastics Co. (Taiwan), polymide and FR-4 and the associated prepreg has such ingredients that the basis point of thermal lamination reaches 170±5° C. Therefore, a prepared circuit board made by directly laminating will not be able to pass the thermal stress testing under the qualification requirement for circuit board IPC-6012. The reliability and electric characteristic of the circuit board and the practicality of the circuit board will be challenged.

2. In each of the plurality of laminates, it is necessary to perform the conducting metals and, thus, position precision needs to be controlled for the conducting metals of each laminate. More time, labor and monetary costs are required. Moreover, a larger offset in alignment between the laminates under thermal lamination is probable, so that the largest diameter of the circuit board is limited to 6 in, if the circuit board is manufactured according to the prior art shown in FIG. 2 in company of existing equipment in the industry. A bottle neck will break the requirement for a probe with a high density and high number of legs to apply to tests for high-density IC's, and for a board with a large area.

In view of that the application of conventional design and manufacture for IC testing cards has met a bottle neck, the present inventor, through a long-term study and practice, has set about the work of improvement and innovation that provides the inventive fine pitch testing substrate structure, in which the wiring space within the fine pitches can be enlarged by means of a circuit design with through holes, blind vias and stack vias, in association with process technologies for fine lines, blind vias, buried vias and filling vias.

### SUMMARY OF THE INVENTION

The primary aspect of the present invention is to provide a testing substrate for checking an IC or packaged dies having a fine pitch. The wiring space within the fine pitch can be enlarged by means of a circuit design with through holes and blind vias, in association with process technologies for fine lines, blind vias, buried vias and filling vias. The enlarged wiring space is applicable to an IC testing substrate having a high number of contacts for the electric test.

To fulfill the above inventive aspect, a circuit design with through holes, blind vias and buried vias is invented so as to enlarge the wiring space that can be set for fine pitch IC testing. On one end of the product, there is disposed a metal pad of the testing contact; on the other end, there is disposed a contact of a testing pin. Signals are integrated and transmitted through the probes on the middle probe base.

The present invention is to be applied to IC testing. Besides, the present invention is applied to designing/manufacturing the laminates of the IC testing card, comprising the following points. First, a plurality of blind vias 412 is designed on the die pad 411 over a probe contact laminate 410; second, signals, power signals and GND (ground) signals, respectively, are distributed to a plurality of access points on the outside by leads in the pads of a BGA (ball grid array) packaged device; third, the signals are subsequently guided to each laminate through the through holes from a plurality of contacts.

Take a substrate having ten laminates for example. The method of manufacturing the same comprises the following steps. First, drill a laminate to form vias; second, electrically plate the vias; third, place copper paste into the vias, and electrically plate the via with copper; fourth, fabricate the wires, and laminate the laminates of the substrate; fifth, drill to form through holes, and fabricate the blind vias; sixth, electrically plate the vias, and fill certain vias; seventh, fabricate outer wires, and make solder masks.

### BRIEF DESCRIPTION OF THE DRAWINGS

The drawings disclose an illustrative embodiment of the present invention which serves to exemplify the various advantages and objects hereof, and are as follows.

FIG. 1 is a partially expanded view of a conventional IC testing card.

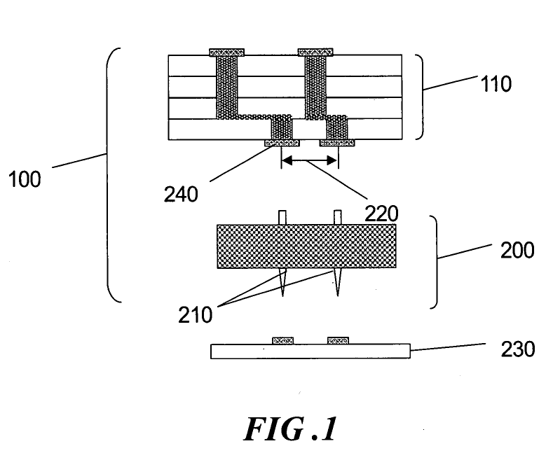

FIG. 2 shows a method of manufacturing conventional IC testing cards.

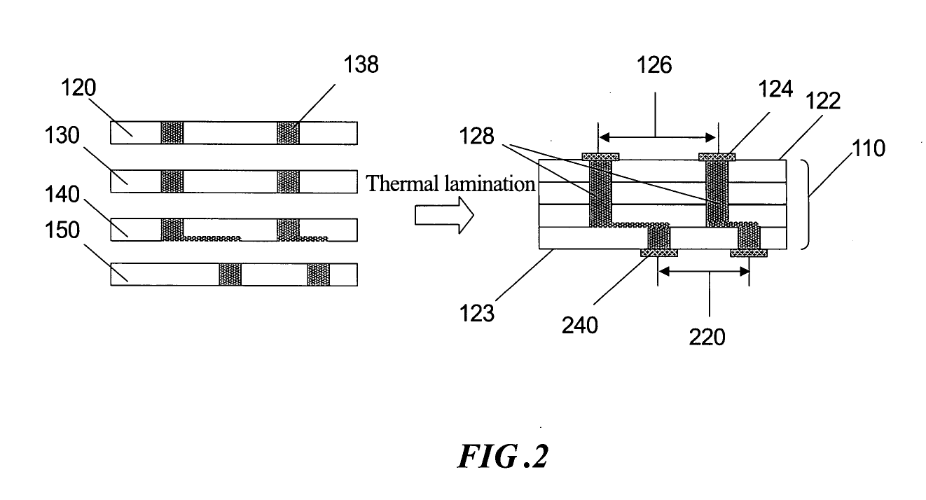

FIG. 3 is a sectional view of the fine pitch testing substrate structure provided by the present invention.

FIG. 4 is a circuit design illustration of the fine pitch testing substrate provided by the present invention.

FIG. 5 is an exploded view illustrating the manufacture of the fine pitch testing substrate provided by the present invention.

FIG. 6 is a combination view of the fine pitch testing substrate structure provided by the present invention.

### DESCRIPTION OF THE PREFERRED EMBODIMENT

The following embodiments accompanying the drawings are described in details, so that the objectives, the shape, the construction, the features and the functions can be understood and appreciated further.

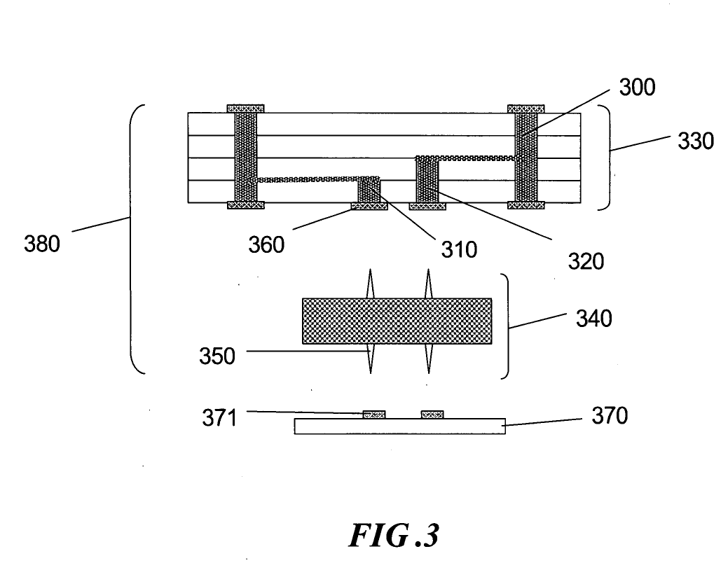

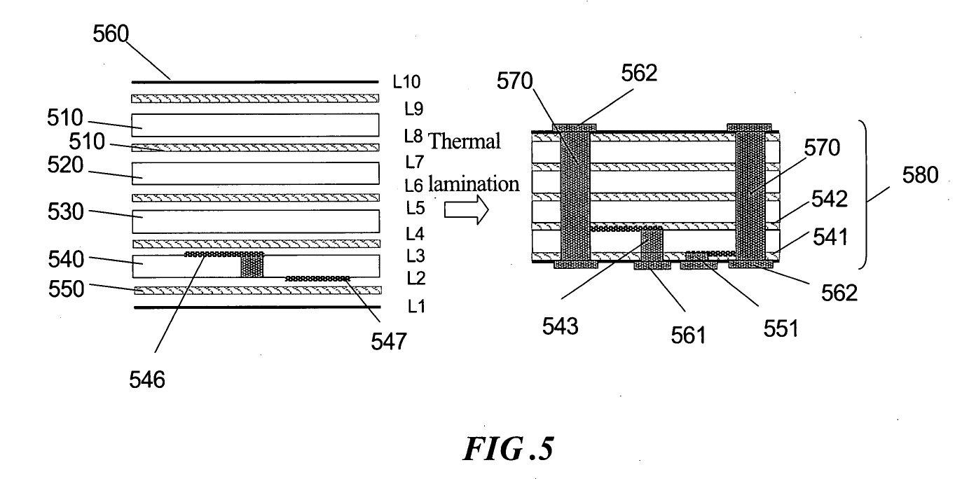

Referring to FIG. 3 to FIG. 6, an embodiment of the present invention is shown in expanded schematic views, which relates to a fine pitch testing substrate structure and the method of manufacturing the same. The fine pitch testing substrate structure comprises a probe base 340, which has a plurality of probes, a testing substrate 330, which has a plurality of laminates, the testing substrate having a plurality of probe contacts each combining with a probe to form a testing machine contact for transmitting signals to a testing machine, and a plurality of substrate circuits 300, 310, 320 and 360, through which signals gathered by the probes can be transmitted to the testing machine contacts.

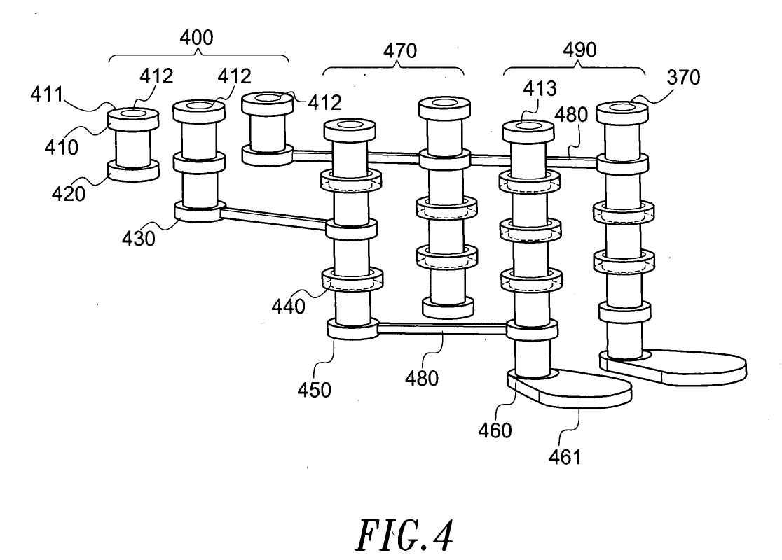

Referring to FIG. 4, the fine pitch testing substrate structure is designed as follows.

First, a plurality of blind vias 412 is designed on the die pad 411 over the probe contact laminate 410, the blind via 412 having one opening thereof connected to the via ring of the outermost laminate and being drilled incompletely to have a cup shape.

Second, signals, power signals and GND (ground) signals are, respectively, distributed to a plurality of through holes 413 in a second zone 470 by leads in a first zone 400 (including an upper surface layer 420 and a lower surface layer 430 of the laminate that is the closest to the probe contact laminate 410), so that the signals can be shunted to each laminate and, as well, to an isolating annulus 440 through the through holes 413 and transmitted by leads (480), and finally the test signals can be sent to the testing machine by the tin pads 461 of testing machine contacts 460 in a third zone 490.

A method of manufacturing the fine pitch testing substrate according to the present invention comprises the following steps. First, drill a laminate from the its upper surface to its lower surface, the laminate being the closest one to the probe contact laminate, so that a bridge of signal communication is formed between the two surface layers; second, drill the laminate to form vias, electrically plate the vias, and use copper as the medium for signal communication between the two surface layers; third, place copper paste into the vias, and electrically plate the vias by using copper, the copper paste serving for buried vias, each of which forms the bottom of a stack via; fourth, fabricate wires on each of the laminates; fifth, place prepreg between the copper laminates and the laminates and perform lamination; sixth, after thermal lamination, drill to form through holes between the copper laminates, and fabricate blind vias between one of the copper laminates and the lower surface layer of the laminate that is the closest one to the probe contact laminate; seventh, electrically plate and fill the vias to form the medium for transmitting signals between the laminates; eighth, fabricate wires on the copper laminates.

An embodiment follows that the method of manufacturing a substrate having ten laminates comprises the following steps.

1. A laminate 540 is drilled from the its upper surface 542 to its lower surface 541, the laminate 540 being the closest one to the probe contact laminate, so that a bridge of signal communication is formed between the two surface layers.

2. The laminate 540 is drilled to form vias, the vias are electrically plated, and copper is used as the medium for signal communication between the two surface layers.

3. Copper paste is placed into the vias, and the vias are electrically plated by using copper, the copper paste serving for buried vias 543 within the interior of multiple substrates and not communicating with outer laminates, and each of the buried vias is stacked under a blind via to form a stack via 320.

4. Wires 546, 547 on each of the laminates 510, 520, 530, 540 are fabricated.

5. Prepreg 550 is placed between the copper laminates 500, 560 and the laminates 510, 520, 530, 540, and lamination is performed.

6. After thermal lamination, drilling is performed to form through holes 570 formed between the copper laminates 500, 560, and blind vias 551 are fabricated between the copper laminate 500 and the lower surface layer 541 of the laminate that is the closest one to the probe contact laminate, wherein the blind vias 551 are fabricated by using UV-YAG laser.

7. The vias are electrically plated and filled to form the medium for transmitting signals between the laminates 510, 520, 530, 540.

8. On the copper laminates 500, 560, wires including a probe contact 561 and a testing contact 562, are fabricated.

Thus, the testing substrate structure is finished, in which the wiring space within the fine pitches can be enlarged effectively.

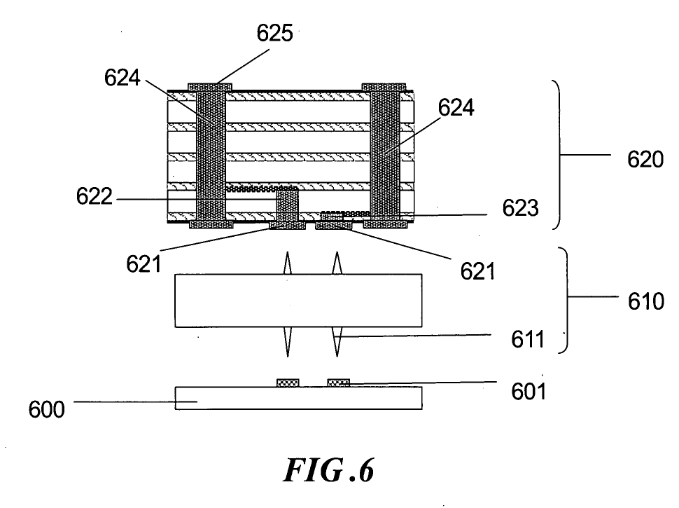

The present invention provides a fine pitch testing substrate structure and a method of manufacturing the same. As shown in FIG. 6, when an IC device 600 is tested, the test signal is sent via testing contacts 601, transmitted by probes 611 on the probe base 610, and directly sent to testing machine contacts 625 by blind buried vias 622 and blind vias 623, respectively, through wires and through holes 624. The values of signals are evaluated by the hardware/software embedded in the testing machine, for determining the quality of the device.

According to the present invention, the design featuring a decreased number of substrates and an increased density of wires in wiring, in association with the novel method of manufacturing, fulfills the test for articles with fine pitches as required in the present or in the future. The product designed and manufactured according to the present invention not only has wide application in practice, but also is cost and time saving.

The above disclosure is related to the detailed technical contents and features thereof. People skilled in this field may proceed with a variety of modifications and replacements based on the disclosures and suggestions of the invention as described without departing from the characteristics thereof.

What is claimed is:

1. A fine pitch testing substrate structure comprising:
a plurality of probes;
a probe base, having the plurality of probes disposed thereon; and
a testing substrate, made of a plurality of laminates, the testing substrate having a plurality of probe contacts each combining with a probe to form a testing machine contact for transmitting signals to a testing machine, and the testing substrate having a plurality of substrate circuits, through which signals gathered by the probes can be transmitted to the testing machine contacts.

2. A method of manufacturing the fine pitch testing substrate structure of claim 1, the method comprising:
drilling a laminate from the its upper surface to its lower surface, the laminate being the closest one to the probe contact laminate, so that a bridge of signal communication is formed between the two surface layers;
drilling the laminate to form vias, electrically plating the vias, and using copper as the medium for signal communication between the two surface layers;
placing copper paste into the vias, and electrically plating the vias by using copper, the copper paste serving for buried vias, each of the buried vias forming the bottom of a stack via;
fabricating wires on each of the laminates;
placing prepreg between the copper laminates and the laminates and performing lamination;
after thermal lamination, drilling to form through holes between the copper laminates, and fabricating blind vias between one of the copper laminates and the lower surface layer of the laminate that is the closest one to the probe contact laminate;
electrically plating and filling the vias to form the medium for transmitting signals between the laminates; and
fabricating wires on the copper laminates.

3. The fine pitch testing substrate structure of claim 1, wherein the circuit on the testing substrate includes blind buried vias.

4. The fine pitch testing substrate structure of claim 1, wherein the circuit on the testing substrate includes blind vias.

5. The fine pitch testing substrate structure of claim 1, wherein the circuit on the testing substrate includes fine lines.

6. The fine pitch testing substrate structure of claim 1, wherein the circuit on the testing substrate includes through holes.

7. The fine pitch testing substrate structure of claim 1, wherein the pitch between two probe contacts is less than 500 micrometers.

8. The fine pitch testing substrate structure of claim 7, wherein the blind vias serving for transmitting test signals through a plurality of IC probe contacts on the probe contact laminates, the plurality of IC probe contacts being produced by means of via filling and wire fabricating.

9. The fine pitch testing substrate structure of claim 1, wherein the testing substrate has a plurality of through holes disposed in the periphery thereof, the through holes serving for transferring drained signals to the testing machine.

10. The fine pitch testing substrate structure of claim 1, wherein the testing substrate has a plurality of buried vias disposed through from the upper surface to the lower surface of the laminate that is the closest one to the probe contact laminate, the buried vias having copper paste placed therein and being electrically plated so that a plurality of signal transferring points is formed on the laminate that is the closest one to the probe contact laminate and signals can be guided and transmitted by wires towards the periphery of the testing substrate.

11. The method of claim 2, wherein the blind vias are fabricating by using UV-YAG laser.

12. The fine pitch testing substrate structure of claim 2, wherein the blind vias is disposed between the probe contact laminate and the lower surface layer of the laminate that is the closest one to the probe contact laminate or between the probe contact laminate and the upper surface layer of the laminate that is the closest one to the probe contact laminate, and signals, power signals and GND signals are, respectively, distributed through the wires on the upper surface layer and the lower surface layer of the laminate that is the closest one to the probe contact laminate and transmitted towards the periphery of the testing substrate.
